(19) United States
(12) Patent Application Publication
(10) Pub. No.: US 2009/0266601 A1
(43) Pub. Date: Oct. 29, 2009

(54) PROTECTIVE COVER FOR PREVENTION OF ELECTROMAGNETISM INTERFERENCE

(76) Inventor: Yu-Jen CHENG, Taipei City (TW)

Correspondence Address: HDLS Patent & Trademark Services, P.O. BOX 220746, CHANTILLY, VA, 20153-0746, US

(21) Appl. No.: 12/108,678

(22) Filed: Apr. 24, 2008

(51) Int. Cl. H05K 9/00

(52) U.S. Cl. 174/377

(57) ABSTRACT

A protective cover for prevention of electromagnetism interference includes a shell and a metal cladding layer. The shell is comprised of a plastic material, and includes a base plate. An edge of the base plate bends upwardly with respect to the base plate and forms an enclosure plate. At least one separator is disposed on the base plate inside of the enclosure plate. The base plate, the enclosure plate and the at least one separator cooperatively define a plurality of isolation areas.

### BACKGROUND

The present invention relates to protective covers, and particularly to a protective cover for prevention of electromagnetism interference.

Most of communication products are high frequency products. Electronic components inside of these communication products are easy to produce electromagnetic waves. Particularly, in these communication products, some electronic components or modules mounted on a printed circuit board may generate interferential electromagnetic waves, thereby affecting a quality of signal transmission. In order to overcome the problem of electromagnetism interference, a shield is disposed around the electronic components or modules to prevent the electromagnetism interference from happen between electronic components and/or modules.

A conventional method for manufacturing a shield configuration for prevention electromagnetism interference is described in the following. A printed circuit board having a number electronic components mounted thereon is provided. A number of metal covers function as shields and are applied to each of the electronic components separately. Specifically, a solder paste is applied to a portion of copper circuits of the printed circuit board. An end surface of each of the metal covers is aligned with and mounted on the corresponding copper circuits and the solder past applied to the copper circuits, thereby obtaining a combination configuration of the printed circuit board and the metal covers (i.e. the shield configuration). Then, the combination configuration is placed in a reflow soldering furnace, thus the metal covers and the printed circuit board are welded together using the solder paste, thereby accomplishing the assembly of the metal covers and the printed circuit board, that is, accomplishing the manufacture of the shield configuration.

However, in practical application, the above-mentioned conventional method for manufacture of the shield configuration has following problems. Because each of the metal covers is mounted on the printed circuit board one by one, massive manpower is need to perform the aligning and mounting processes. In addition, because the metal covers and the printed circuit board are combined together using the soldering manner, once issues/errors occur in the assembly process, the combination configuration of the printed circuit board and the metal covers can not be detached, as a result, the combination configuration having the issues/errors must be discarded and be thrown away, thereby causing waste of materials and increasing cost of the manufacture of the shield configuration. Furthermore, the metal covers have a relative high cost of materials, and the combination configuration of the printed circuit board and the metal covers has a heavy structure, which is not concordance with the development trends of lightness of the communication products.

### BRIEF SUMMARY

A purpose of the present invention provides a protective cover having a function for prevention of electromagnetism interference. In the present protective cover, a number of isolation areas are directly molded together with the manufacture of a shell of the protective cover, thereby preventing the electromagnetism interference from happening between modules in different isolation areas.

Furthermore, another purpose of the present invention provides a protective cover having a function for prevention of electromagnetism interference. In the present protective cover, a shell of the protective cover has an integrated structure, thus can shorten process and lower the manufacture cost.

Moreover, another purpose of the present invention provides a protective cover having a function for prevention of electromagnetism interference. In the present protective cover, the shell of the protective cover is made of a plastic material, thus can lighten a weight of the protective cover and facilitate the manufacture of the protective cover.

In addition, another purpose of the present invention provides a protective cover having a function for prevention of electromagnetism interference. In the present protective cover, the shell of the protective cover is combined with a main body of a communication product using positioning components such as bolts, and an electrically conductive adhesive is applied therebetween, thus, overcoming an unevenness of an interface of the shell and the main body of a communication product. Also, the protective cover and the main body of the communication product can be detached and used repeatedly.

An embodiment of a protective cover includes a shell and a metal cladding layer. The shell is comprised of a plastic material and includes a base plate. An edge of the base plate bends upwardly with respect to the base plate and forms an enclosure plate surrounding the base plate. At least one separator is disposed on the base plate inside of the enclosure plate. As a result, the base plate, the enclosure plate, and the at least one separator cooperatively define a number of closed isolation areas without communicating with each other. The metal cladding layer is formed or coated on inner surfaces of the base plate, the enclosure plate, and the at least one separator.

Another embodiment of a protective cover includes a shell and a metal cladding layer. The shell is comprised of a plastic material and includes a base plate. An edge of the base plate bends upwardly with respect to the base plate and forms an enclosure plate surrounding the base plate. At least one separator is disposed on the base plate inside of the enclosure plate. As a result, the base plate, the enclosure plate, and the at least one separator cooperatively define a number of closed isolation areas without communicating with each other. The metal cladding layer is formed or coated on outer surfaces of the base plate, the enclosure plate, and the at least one separator.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 shows a three-dimensional view of a protective cover, in accordance with a first embodiment.

FIG. 2 shows a cutaway view of the protective cover of FIG. 1 along the line 2-2.

FIG. 3 shows an exploded view of the protective cover and a main body of a mobile phone.

FIG. 4 shows an assembly view of the protective cover and the main body of the mobile phone.

FIG. 5 shows a cutaway view of FIG. 4 along the line 5-5.

FIG. 6 shows an enlarged view inside of the circle A of FIG. 5.

FIG. 7 shows a three-dimensional view of a protective cover, in accordance with a second embodiment.

### DETAILED DESCRIPTION

Embodiments will be described in detail below and with reference to the drawings.

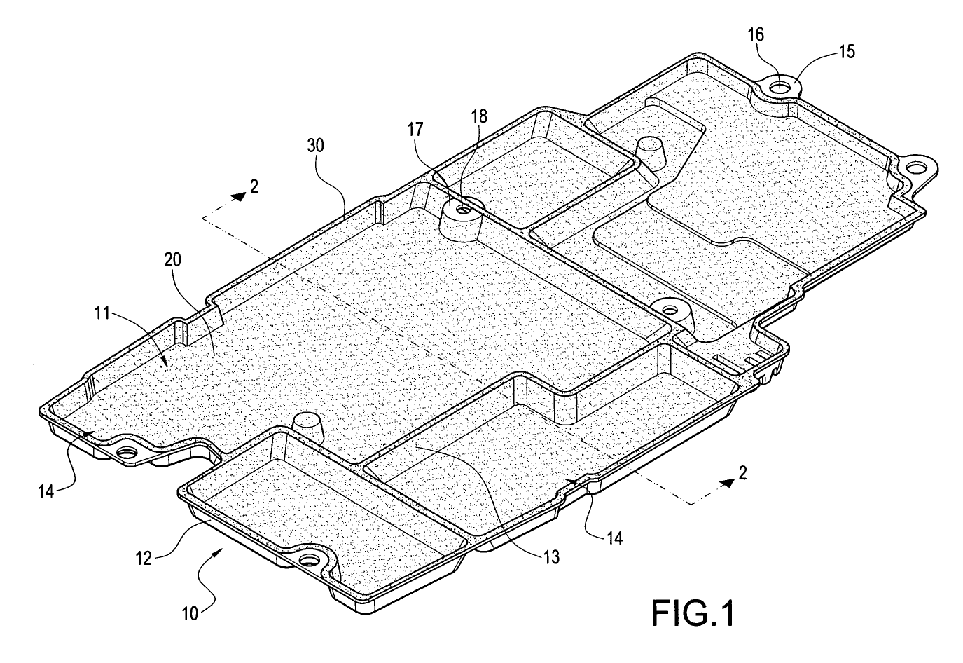

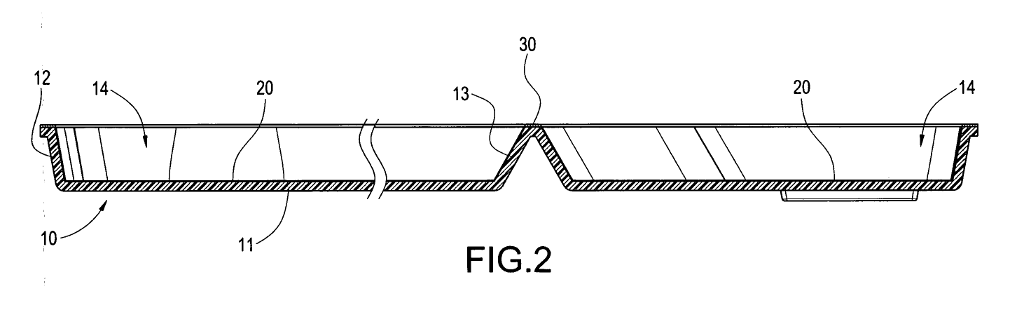

Referring to FIG. 1 and FIG. 2, a protective cover for prevention of electromagnetism interference, in accordance with a first embodiment is shown. The protective cover includes a shell 1 and a metal cladding layer 20.

Configuration and size or the shell 1 can be predetermined according to a desired communication product. The shell 1 is made of plastic material and is an integrated structure manufactured using a heat pressing method. The plastic material can be a material selected from a group consisting of polystyrene (PS), polycarbonate (PC), acrylonitrile-butadiene-styrene (ABS), prepreg (PP), Polyethylene Terephthalate (PET), polytetrafluoroethylene (PEEK), polytetrafluoroethylene (PTFE) and polyimide (PI). The shell 1 includes a base plate 11, and an edge of the base plate 11 bends upwardly with respect to the base plate 11 (i.e., perpendicular to the base plate 11) and forms an closed enclosure plate 12 surrounding the base plate 11. At least one separator 13 is disposed on the base plate 11 inside of the enclosure plate 12. In the present embodiment, four separators 13 are disposed on the base plate 11 inside of the enclosure plate 12. A height of each of the separators 13 is identical with that of the enclosure plate 12. As a result, the base plate 11, the enclosure plate 12, and the separators 13 cooperate to define a number of closed isolation areas 14 without communicating with each other. In addition, a number of ledges 15 extend/protrudes from an edge of a top surface of the enclosure plate 12. A first fixing hole is opened in a center of each of the ledges 15. Furthermore, at least one cylindrical column 17 is formed in a portion of the separators 13, and a second fixing hole 18 is opened in each of the cylindrical column 17.

The metal cladding layer 20 is formed or coated on inner surfaces of the base plate 11, the enclosure plate 12 and the separators 13 employing a deposition method. The deposition method can be a chemical deposition method or a physical deposition method. The physical deposition method includes a sputtering method, an evaporation method, and so on. In the present embodiment, the metal cladding layer 20 is deposited on the inner surfaces of the base plate 11, the enclosure plate 12 and the separators 13 employing the sputtering method.

In addition, the protective cover additionally includes an electrically conductive adhesive 30. The electrically conductive adhesive 30 is adhered to top surfaces of the enclosure plate 12 and the separators 13.

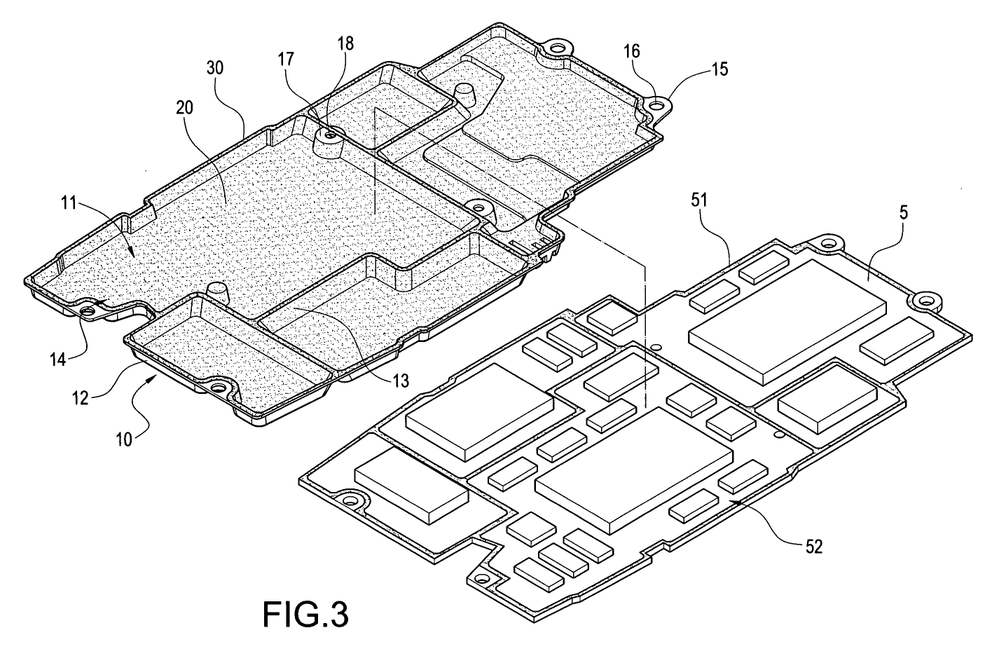

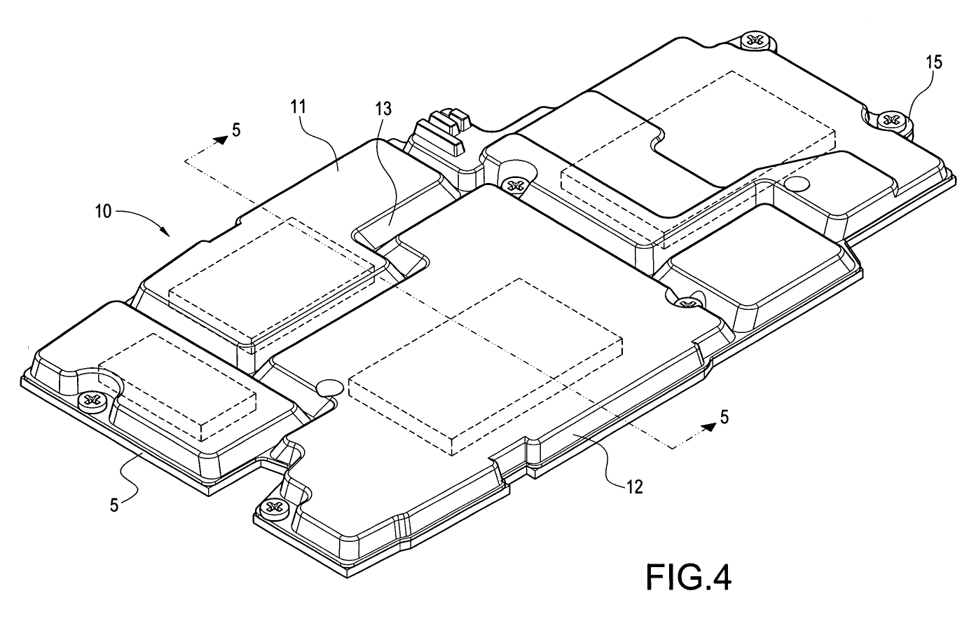

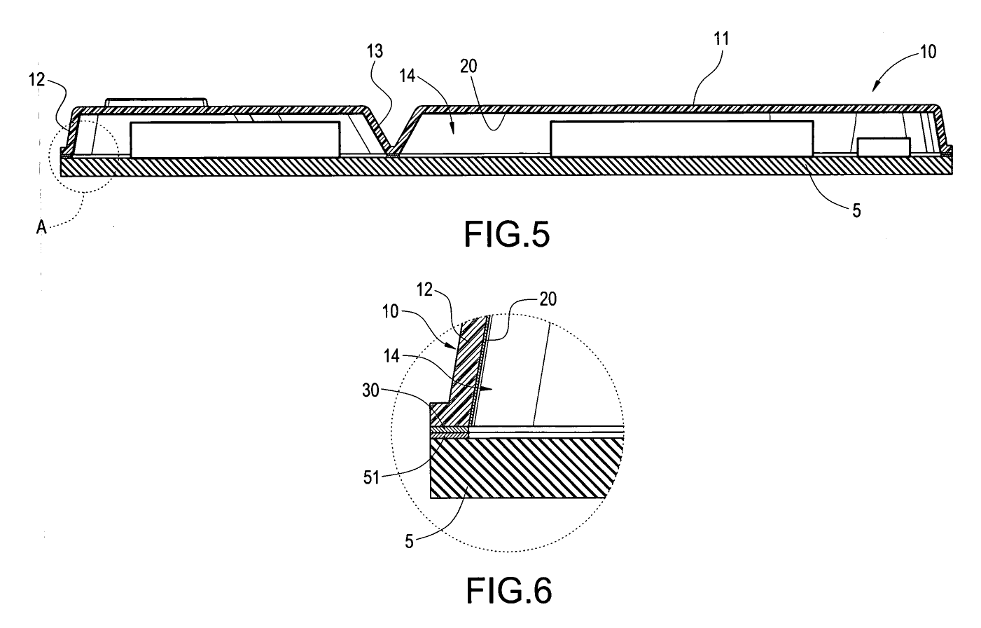

Referring to FIGS. 3-6, the protective cover can be applied to communication products. For example, the protective cover is applied to a main body 5 of a mobile phone. A closed copper circuit 51 is formed on a surface of the main body 5, and a configuration of the copper circuit 51 corresponds to that of the enclosure plate 12. A number of wireless modules 52 are disposed on the surface of the main body 5. Each of the wireless modules 52 is composed of at least one electronic component. In a process of assembling the protective cover and the main body 5, the plastic board 10 (i.e., the shell 1) is placed on the main body 5, and the copper circuit 51 contacts and combines with the enclosure plate 12 by the electrically conductive adhesive 40. Then, the protective cover is fixed on the main body 5 using positioning components such as bolts passing through the corresponding first and second fixing holes 16, 18 and being fixed on the main body 5. Thus, the protective cover and the main body 5 are combined together tightly, thereby an effect of prevention of electromagnetism interference of the protective cover is greatly improved.

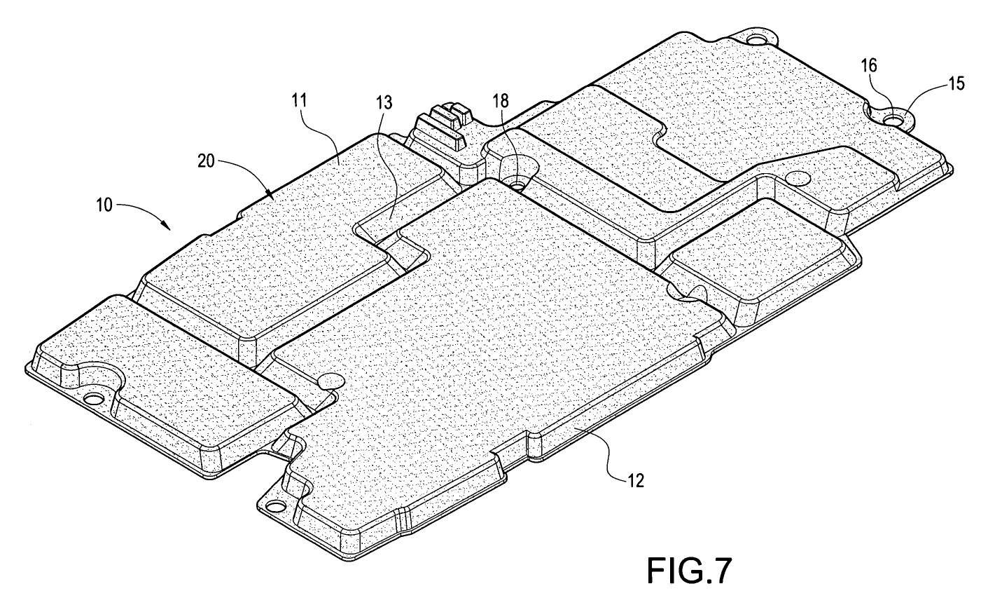

Referring to FIG. 7, a protective cover, in accordance with a second embodiment, is shown. The protective cover of the present embodiment is similar with the protective cover of the first embodiment, except the position of the metal cladding layer 20. In the present embodiment, the metal cladding layer 20 is formed or coated on outer surfaces of the base plate 11, the enclosure plate 12, and the separators 13.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A protective cover for prevention of electromagnetism interference, comprising:
a shell comprised of a plastic material, the shell comprising a base plate, an edge of the base plate bending upwardly with respect to the base plate and forming an enclosure plate, at least one separator being disposed on the base plate inside of the enclosure plate, the base plate, the enclosure plate and the at least one separator cooperatively defining a plurality of isolation areas; and
a metal cladding layer formed on inner surfaces of the base plate, the enclosure plate and the at least one separator.

2. The protective cover as claimed in claim 1, wherein the shell is an integrated structure.

3. The protective cover as claimed in claim 1, wherein each of the isolation areas is closed and is not communicating with each other.

4. The protective cover as claimed in claim 1, wherein the plastic material is a material selected from a group consisting of PS, PC, ABS, PP, PET, PEEK, PTFE and PI.

5. The protective cover as claimed in claim 1, wherein a height of the at least one separator is identical with a height of the enclosure plate.

6. The protective cover as claimed in claim 1, wherein a plurality of ledges formed extending/protruding from an edge of a top surface of the enclosure plate, and a first fixing hole is opened in a center of each ledge.

7. The protective cover as claimed in claim 1, wherein at least one cylindrical column is formed on the at least one separator, and a second fixing hole is opened in the cylindrical column.

8. The protective cover as claimed in claim 1, wherein the protective cover additionally comprises an electrically conductive adhesive applied to top surfaces of the enclosure plate and the at least one separator.

9. A protective cover for prevention of electromagnetism interference, comprising:
a shell comprised of a plastic material, the shell comprising a base plate, an edge of the base plate bending upwardly with respect to the base plate and forming an enclosure plate, at least one separator being disposed on the base plate inside of the enclosure plate, the base plate, the enclosure plate and the at least one separator cooperatively defining a plurality of isolation areas; and
a metal cladding layer formed on outer surfaces of the base plate, the enclosure plate and the at least one separator.

10. The protective cover as claimed in claim 9, wherein the shell is an integrated structure.

11. The protective cover as claimed in claim 9, wherein each of the isolation areas is closed and is not communicating with each other.

12. The protective cover as claimed in claim 9, wherein the plastic material is a material selected from a group consisting of PS, PC, ABS, PP, PET, PEEK, PTFE and PI.

13. The protective cover as claimed in claim 9, wherein a height of the at least one separator is identical with a height of the enclosure plate.

14. The protective cover as claimed in claim 9, wherein a plurality of ledges formed extending/protruding from an edge of a top surface of the enclosure plate, and a first fixing hole is opened in a center of each ledge.

15. The protective cover as claimed in claim 9, wherein at least one cylindrical column is formed on the at least one separator, and a second fixing hole is opened in the cylindrical column.

16. The protective cover as claimed in claim 19, wherein the protective cover additionally comprises an electrically conductive adhesive applied to top surfaces of the enclosure plate and the at least one separator.
